(19) United States
(12) Patent Application Publication
(10) Pub. No.: US 2015/0206930 A1
(43) Pub. Date: Jul. 23, 2015

(54) LIGHT-EMITTING DEVICE WTIH OXIDE THIN FILM TRANSISTORS AND MANUFACTURING METHOD THEREOF

(71) Applicant: SHENZHEN CHINA STAR OPTOELECTRONICS TECHNOLOGY CO., LTD., Shenzhen (CN)

(72) Inventor: Sai-Chang Liu, Shenzhen (CN)

(21) Appl. No.: 14/240,371

(22) PCT Filed: Jan. 17, 2014
(86) PCT No.: PCT/CN2014/070841

§ 371 Date: Jun. 3, 2014

(51) Int. Cl. H01L 27/32; H01L 27/12; H01L 21/02; H01L 29/786

(52) U.S. Cl. CPC H01L 27/3272; H01L 27/3246; H01L 29/7869; H01L 27/1259; H01L 21/02565; H01L 2227/323

(57) ABSTRACT

The present disclosure disclosed a light-emitting device with thin film transistors, comprising: a substrate and a substrate insulating layer formed thereon; a gate electrode, a source electrode, and a drain electrode. The gate electrode is arranged on the substrate insulating layer, and a gate insulating layer is formed between the gate electrode and the electrodes of the source and the drain. An oxide semiconductor layer comprises a resource region and a drain region being in electric contact with the source electrode and the drain electrode respectively and a channel region for providing a conductive channel therebetween. A passivation layer is arranged on a part of the gate insulating layer, the source electrode, the drain electrode, and the oxide semiconductor layer. A shielding layer is arranged on the passivation layer for shielding the external light from illuminating on the oxide semiconductor layer. The present device can increase the conductive performance and stability of the component.

### FIELD OF THE INVENTION

The present disclosure relates to the field of semiconductor manufacturing technologies, in particular to a light-emitting device with oxide thin film transistors (Oxide TFTs) and a manufacturing method for the same.

### BACKGROUND OF THE INVENTION

At present, oxide thin film transistors (Oxide TFTs) are widely used in integrated circuits (ICs) and image display device drive circuits relying on the excellent performances thereof. A channel layer of a transistor, as a channel for transmitting charges between a source electrode and a drain electrode of a TFT device, is an important structure of the TFT device. The structure and performance of the channel layer directly affect the electrical performance of a product being made of the device. The channel layer may be consisted of a semiconductor thin film material which is known as a silicon-based semiconductor material, as well as an oxide semiconductor material, etc. An example of the oxide semiconductor material is Indium Gallium Zinc Oxide (IGZO for short).

Under normal conditions, the oxide semiconductor materials are very sensitive to light, and especially to ultraviolet light. In the case that the channels of an oxide semiconductor layer are irradiated by a light, electron holes generated due to a photoelectric effect have great influence on the electric performances and stability of components. With regard to an organic top-emission light-emitting device (Top-emission LED) composed of oxide thin film transistors with a co-planar (CP) structure or a BCE (back channel etched) structure; an external light is inevitably irradiated on the channel region of the oxide semiconductor layer.

Therefore, in order to prevent the semiconductor oxide layer from being influenced by the external light and thus reducing the conductive characteristics and stability thereof, a TFT device or a TFT device preparation process capable of protecting the semiconductor oxide layer is needed.

### SUMMARY OF THE INVENTION

In order to solve the above-mentioned technical problems, the present disclosure provides a light-emitting device with thin film transistors, comprising:

a substrate and a substrate insulating layer formed on the substrate;

a gate electrode, a source electrode, and a drain electrode, wherein the gate electrode is arranged on the substrate insulating layer, and a gate insulating layer is formed between the gate electrode and the electrodes of the source and the drain;

an oxide semiconductor layer, comprising a resource region and a drain region in electric contact with the source electrode and the drain electrode respectively and a channel region configured to provide a conductive channel between the source electrode and the drain electrode;

a passivation layer arranged on a part of the gate insulating layer, the source electrode, the drain electrode, and the oxide semiconductor layer;

a shielding layer arranged on the passivation layer for shielding the external light from illuminating on the oxide semiconductor layer; and

an organic illuminant comprising a first electrode and a second electrode, wherein a part of the first electrode penetrates through the passivation layer to be electrically connected with the source electrode or the drain electrode.

According to an embodiment of the present disclosure, the shielding layer and the first electrode are formed on the passivation layer simultaneously, wherein the shielding layer is a part of the first electrode extending on the upper surface of the passivation layer.

According to an embodiment of the present disclosure, the shielding layer and the first electrode are formed on the passivation layer simultaneously, wherein the shielding layer is spaced from the first electrode are spaced in a distance.

According to an embodiment of the present disclosure, a pixel defined layer is formed on a part of the passivation layer as well as the first electrode and the shielding layer, with an opening placed thereon to expose a part or whole of the upper surface of the first electrode.

According to an embodiment of the present disclosure, the organic light-emitting material layer of the organic illuminant and a second electrode are arranged in the opening.

According to an embodiment of the present disclosure, the oxide semiconductor layer is arranged on a part of the gate insulating layer as well as the source electrode and the drain electrode.

According to an embodiment of the present disclosure, the source electrode and the drain electrode are arranged on the oxide semiconductor layer.

According to another aspect of the present disclosure, a method for manufacturing a light-emitting device with an oxide thin film transistor is also provided, comprising the following steps:

forming a substrate insulating layer on a substrate;
forming a gate electrode on the substrate insulating layer;
forming a gate insulating layer on the gate electrode and a part of the substrate insulating layer;
forming a source electrode and a drain electrode on the gate insulating layer, and then forming an oxide semiconductor layer on the gate insulating layer, wherein the oxide semiconductor layer comprises a source region and a drain region in contact with the source electrode and the drain electrode respectively and a channel region, so that the channel region is located between the source electrode and the drain electrode to form a conductive channel therebetween;

limiting a passivation layer on a part of the gate insulating layer, the source electrode, the drain electrode, and the oxide semiconductor layer;
forming, on the passivation layer, a first electrode of an organic illuminant, a part of which penetrates through the passivation layer to contact with the source electrode or the drain electrode; and forming a shielding layer to cover the whole oxide semiconductor layer at the time of forming the first electrode.

According to an embodiment of the present disclosure, the first electrode is extended along the upper surface of the passivation layer to form the shielding layer.

According to an embodiment of the present disclosure, the first electrode is spaced from the shielding layer in a certain distance.

According to an embodiment of the present disclosure, a pixel defined layer is formed on a part of the passivation layer as well as the first electrode and the shielding layer, with an opening being formed thereon to expose a part or whole of the upper surface of the first electrode.

According to another aspect of the present disclosure, a method for manufacturing a light-emitting device with an oxide thin film transistor is also provided, comprising the following steps:

forming a substrate insulating layer on a substrate;

forming a gate electrode on the substrate insulating layer;

forming a gate insulating layer on the gate electrode and a part of the substrate insulating layer;

forming, on the gate insulating layer, an oxide semiconductor layer comprising a source region, a drain region, and a channel region;

then, forming, on the gate insulating layer, a source electrode and a drain electrode being in contact with the source region and the drain region respectively;

forming a passivation layer on a part of the gate insulating layer, the source electrode, the drain electrode, and the oxide semiconductor layer;

forming, on the passivation layer, a first electrode of an organic illuminant, a part of which penetrates through the passivation layer to contact with the source electrode or the drain electrode; and

forming a shielding layer to cover the whole oxide semiconductor layer at the time of forming the first electrode.

According to an embodiment of the present disclosure, the first electrode is extended along the upper surface of the passivation layer to form the shielding layer.

According to an embodiment of the present disclosure, the first electrode is spaced from the shielding layer in a certain distance.

According to an embodiment of the present disclosure, a pixel defined layer is formed on a part of the passivation layer as well as the first electrode and the shielding layer, with an opening being formed thereon to expose a part or the whole of the upper surface of the first electrode.

The light-emitting device manufactured by the method of the present disclosure is capable of preventing the semiconductor oxide layer from being influenced by the external light. Therefore the conductive characteristics and stability of components are greatly improved.

Other features and advantages of the present disclosure will be illustrated in the following description, and are partially obvious from the description or understood through implementing the present disclosure. The objectives and other advantages of the present disclosure may be realized and obtained through the structures specified in the description, claims, and accompanying drawings.

### BRIEF DESCRIPTION OF THE DRAWINGS

The accompanying drawings are provided for a further understanding of the present disclosure, constitute a part of the description, and are used for interpreting the present disclosure together with the embodiments of the present disclosure, rather than limiting the present disclosure, in which:

FIG. 1 is a structure diagram of thin film transistor devices used in the prior art;

FIG. 2 is a co-planar structure diagram according to the embodiment of the present disclosure; and

FIG. 3 is a BCE structure diagram according to the embodiment of the present disclosure.

### DETAILED DESCRIPTION OF THE EMBODIMENTS

The embodiments of the present disclosure will be illustrated in detail in conjunction with the accompanying drawings and embodiments, and thus how technical means are applied to solve the technical problems and the implementation process of achieving the technical effects may be fully understood and accordingly implemented. It should be noted that as long as conflicts are avoided, all embodiments in the present disclosure and all features in all the embodiments may be combined together, and the formed technical solutions are within the scope of the present disclosure.

The present disclosure aims at a structure of an OLED (organic light emitting diode) combined with oxide transistors (Oxide TFTs) and a process for manufacturing the same. The conditions of an OLED technology related to the present disclosure are introduced below.

At present, OLEDs already have a trend of gradually replacing LCDs (liquid crystal displays) as display components by virtue of the good display performance. Aiming at an OLED, driving manners for the OLED include an active driving (AMOLED) manner and a passive driving (PMOLED) manner.

The passive driving (PMOLED) is divided into a static driving circuit and a dynamic driving circuit. On an organic light-emitting device with the static driving circuit, the cathodes of the organic electroluminescent pixels each are generally led out by being connected together, and the anodes of the pixels each are separately led out, which is a common-cathode connection manner. If one pixel needs to emit a light, only a premise that the difference between the voltage of a constant-current source and the voltage of the cathode is met, the pixel will emit a light under the driving of the constant-current source, and if one pixel does not emit a light, the pixel can be reversely cut off by connecting the anode of the pixel to a negative voltage. The static driving circuit is generally used for driving for a segmented display screen.

In the dynamic driving manner, the two electrodes of a pixel are configured to be of a matrix-type structure on an organic light-emitting device of dynamic driving, that is, the electrodes with the same property of a group of horizontal display pixels are common, and the electrodes with the same property of a group of longitudinal display pixels are common. If the pixels can be divided into N rows and M columns, N row electrodes and M column electrodes can be provided. The row and the column are corresponding to the two electrodes, that is, the cathode and the anode of a light-emitting pixel, respectively. During a process of actual circuit driving, the pixels need to be lightened row by row or column by column, a row-by-row scanning manner is usually adopted, and the column electrodes are data electrodes.

An application example to be introduced in detail in the present disclosure is an active driving OLED (AM OLED).

Each pixel of active driving is equipped with a thin film transistor with a switch function, for example, a low temperature poly-Si thin film transistor (LTP-Si TFT). In addition, each pixel is further equipped with a charge storage capacitor, and a peripheral driver circuit and the whole system of display arrays are integrated on the same glass substrate. However, the TFT structure which is the same as the TFT structure of LCDs cannot be used for OLEDs. This is due to the fact that LCDs use voltage driving, while OLEDs depend on current driving, and the brightness thereof is in direct proportion to a current magnitude. Therefore, except for the addressing TFTs for switching ON/OFF, there is also a need for small driver TFTs with low impedance which allows a current passing the TFT at its “on” state.

Active driving, belonging to static driving manners, has a storage effect and thus can perform 100% load driving. Since the driving is not limited by the quantity of scanning electrodes, the various pixels can be selectively adjusted independently. Active driving which is not limited by the quantity of scanning electrodes so that a high brightness and a high resolution are easy to realize since there is no problem of duty cycle, is widely used in applications. In addition, the active driving is capable of independently performing grayscale adjustment on the red pixels and the blue pixels of brightness, which facilitates the realization for OLED colorization. The driver circuit of an active matrix is placed in a display screen, so that it is easier to increase the level of integration and miniaturization. In addition, because the problem of connection between a peripheral driver circuit and the screen has been addressed, the yield and reliability are improved to a certain extent.

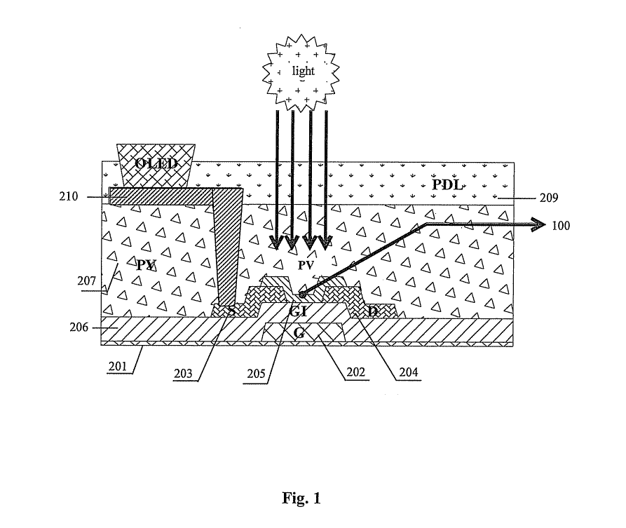

However, as shown in FIG. 1, an oxide semiconductor IGZO in the display components of a top emitting AMOLED (active matrix/organic light emitting diode) in the prior art is influenced by an external light during use, which is indicated by an arrow mark 100, thus causing the condition of unstable electric performances of TFT components, for example, threshold voltage Vₜₕ drift and the like.

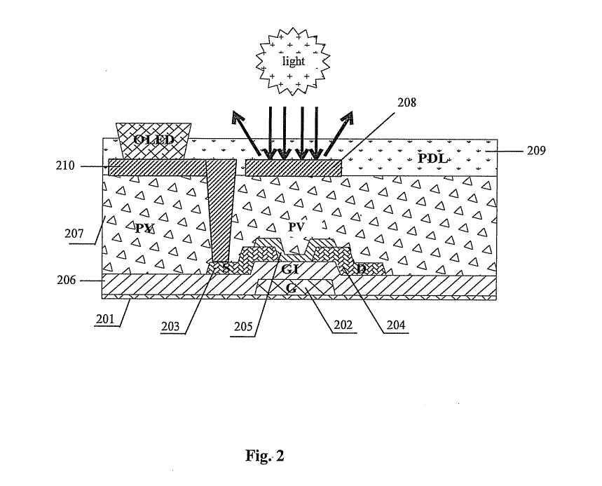

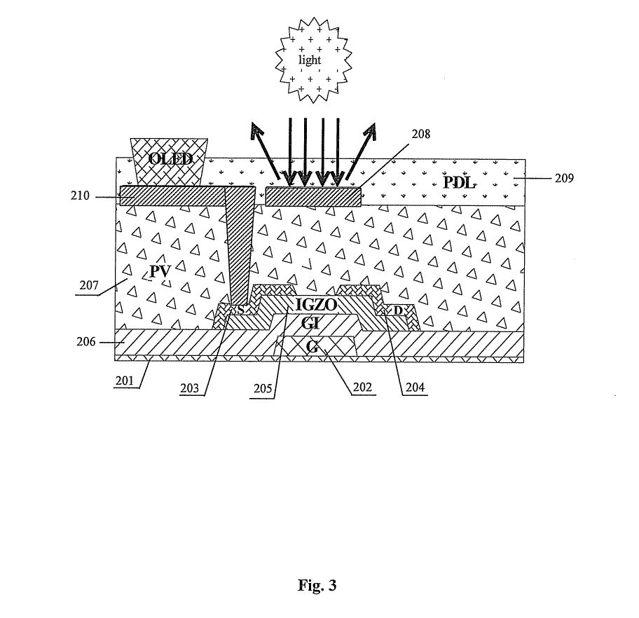

In view of the above problem, according to the present disclosure, when an electrode of the AMOLED, for example, an anode 210 is formed, the electrode is covered on the oxide semiconductor IGZO of a TFT simultaneously, so as to shield the external light. The specific structure refers to FIG. 2 and FIG. 3.

FIG. 2 shows an example of an OLED integrated with TFTs with a co-planar structure, which adopts a top emitting active driving manner. In terms of the composition structure, the OLED comprises a cathode 101, an anode 102, and an organic light-emitting layer 103 therebetween. The anode 102 is in electric contact with one electrode of a TFT, for example, a drain electrode.

With respect to the selection of material for the anode, it is necessary for the material itself having property of a high work function and light transmission. Therefore, a stable ITO (indium tin oxide) transparent conducting film with a high work function of 4.5 eV-5.3 eV is widely applied to anodes. Regarding the cathode part, in order to increase the light-emitting efficiency of the components, and improve the injection of electrons and electron holes, normally metals with low work functions, such as Ag, Al, Ca, In, Li, and Mg, or composite metals with low work functions (e.g., Mg—Ag) are used to produce cathodes.

In the embodiment of the present disclosure, because the OLED is of a top emitting structure, the anode of the OLED in an example adopts a sandwich structure with Ag being between an upper and a lower ITO transparent conducting film.

The TFT structure integrated by the OLED is introduced below.

In FIG. 2, TFTs are in a co-planar (CO) structure, namely, a lower gate bottom contact structure, and Each TFT comprises a substrate 201; a substrate insulating layer formed on the substrate; a gate 202, a source 203 and a drain 204; and an oxide semiconductor layer 205, comprising a resource region and a drain region in electric contact with the source 203 and the drain 204 respectively, and a channel region configured to provide a conductive channel between the source electrode and the drain electrode. A GI (Gate Isolation) layer 206 is arranged between the oxide semiconductor layer 205 and a gate region in electric contact with the gate electrode.

In the co-planar structure, the gate region in electric contact with the gate electrode 202 is arranged below the GI layer 206 relative to the semiconductor oxide layer. Further, in order to protect the devices, a PV (passivation) layer 207 is arranged on the semiconductor oxide layer. In order to prevent the semiconductor oxide layer from being influenced by illumination, a shielding layer 208 is further formed after the PV layer is formed.

In order to limit the light-emitting region of the OLED and expand a gap between the cathode and the anode of the OLED, according to the present disclosure, a pixel defined layer (PDL) is formed on the anode, the shielding layer 208 and a part of the PV layer 207. The formed pixel defined layer 209 is provided with an opening for exposing, for example, the anode.

On the other hand, in order to reduce the number of steps of a photo engraving process (PEP), a production method of forming an electrode of the OLED, for example, the anode 210, and the shielding layer 208 simultaneously is adopted. That is, in the case that the anode 210 of the OLED is formed, the shielding layer 208 is simultaneously formed by patterning.

Because the electrode of the present disclosure adopts the sandwich structure with conducting metal, for example, Ag being between an upper and a lower ITO transparent conducting film, the shielding layer 208 can shield the external light. The adopted material of the oxide semiconductor layer in the embodiment of the present disclosure is an indium gallium zinc oxide (IGZO) material which mainly is sensitive to ultraviolet light. Therefore, when selecting for example the anode material, other materials which can transmit a visible light but cannot transmit ultraviolet light can also be considered.

Depending on whether the electrodes of the OLED are in contact with the sources or the drains of the oxide thin film transistors, the shielding layer 208 can also be formed by patterning when forming the cathode.

FIG. 3 is a cross section diagram of a top emitting AOLED with oxide thin film transistors based on a back channel etch (BCE) process. The difference between FIG. 3 and FIG. 2 lies in processes for forming the channels of the oxide thin film transistors.

The BCE structure shown in FIG. 3 also comprises a substrate 201, a substrate insulating layer (also indicated by 201) formed on the substrate 201, a gate electrode 202, an oxide semiconductor layer 205, a source electrode 203 and a drain electrode 204. The oxide semiconductor layer 205 comprises a resource region and a drain region in electric contact with the source electrode 203 and the drain electrode 204 respectively, and a channel region configured to provide a conductive channel between the source electrode and the drain electrode. A GI (Gate Isolation) layer 206 is arranged between the oxide semiconductor layer 205 and a gate region in electric contact with the gate electrode.

In the structure as shown in FIG. 3, the source electrode and the drain electrode are formed on the oxide semiconductor layer 205. The structure as shown in FIG. 2 is that the oxide semiconductor layer 205 is formed on the source electrode and the drain electrode. However, in any case, the oxide semiconductor layer IGZO is exposed in a range which can be irradiated by the external light. Therefore, after a passivation layer 207 is formed, a shielding layer 208 needs to be formed above the channel region of the oxide semiconductor layer. In order to reduce PEP steps, the shielding layer 208 can be formed while an electrode 210 in contact with one of the source electrode and the drain electrode of a thin film transistor, of the OLED. Finally, a pixel defined layer (PDL) 209 is formed in any one manner disclosed in the prior art.

Compared FIG. 2 with FIG. 3, it can be seen that in FIG. 2, the source region and the drain region also need to be shielded except the channel region, so that the area of the formed shielding layer in FIG. 2 is greater than the area of the shielding layer in FIG. 3.

Processes for manufacturing the structures of the devices shown in FIG. 2 and FIG. 3 are introduced in detail below.

The structure in FIG. 2 can be formed by the following steps:

firstly, forming a substrate insulating layer on a substrate;

then, forming a gate electrode on the substrate insulating layer;

forming a gate insulating layer on the gate electrode and a part of the substrate insulating layer;

forming a source electrode and a drain electrode on the gate insulating layer, and then forming, on the gate insulating layer, an oxide semiconductor layer comprising a source region and a drain region in contact with the source electrode and the drain electrode respectively and a channel region, so that the channel region is located between the source and the drain to form a conductive channel therebetween;

forming a passivation layer on a part of the gate insulating layer, the source electrode, the drain electrode, and the oxide semiconductor layer; and forming, on the PV layer, a first electrode (for example, the anode) of an OLED, a part of which penetrates through the PV layer and then is in contact with the source electrode or the drain electrode of a TFT. As shown in FIG. 2, the first electrode is in contact with the source electrode, but the present disclosure is not limited thereto.

In the case that the first electrode is formed, the first electrode is extended to form a shielding layer to cover the whole oxide semiconductor layer. Optionally, when patterning the shielding layer, a certain space can also be formed between the shielding layer and the first electrode, only if the shielding layer can cover the exposed part of the oxide semiconductor layer. For example, as shown in FIG. 3, it is possible for only covering the channel region, because the source electrode and the drain electrode can shield the light for their own conductive properties.

Then, a pixel defined layer is formed, which is provided with an opening for exposing the first electrode.

Further, an organic material layer OLED and a second electrode are formed in a conventional manner.

The difference of FIG. 3 from FIG. 2 only lies in that the formation of the oxide semiconductor layer is before the formation of the source electrode and the drain electrode, and thus is not described redundantly herein.

Although the embodiments are described above, the foregoing are merely the embodiments for facilitating the understanding of the present disclosure, rather than limiting the present disclosure. Any changes or alternatives conceived by the skilled ones in the art after reading the content disclosed herein will fall within the scope of the present disclosure. Accordingly, the scope of the present disclosure will be defined in the accompanying claims.

What is claimed is:

1. A light-emitting device with thin film transistors, comprising:
a substrate and a substrate insulating layer formed on the substrate;
a gate electrode, a source electrode, and a drain electrode, wherein the gate electrode is arranged on the substrate insulating layer, and a gate insulating layer is formed between the gate electrode and the electrodes of the source and the drain;
an oxide semiconductor layer, comprising a resource region and a drain region in electric contact with the source electrode and the drain electrode respectively, and a channel region configured to provide a conductive channel between the source electrode and the drain electrode;
a passivation layer arranged on a part of the gate insulating layer, the source electrode, the drain electrode, and the oxide semiconductor layer;
a shielding layer arranged on the passivation layer for shielding the external light from illuminating on the oxide semiconductor layer; and
an organic illuminant comprising a first electrode and a second electrode, with a part of the first electrode penetrating through the passivation layer to be electrically connected with the source electrode or the drain electrode.

2. The light-emitting device as recited in claim 1, wherein the shielding layer and the first electrode are formed on the passivation layer simultaneously, and the shielding layer is a part of the first electrode extending on the upper surface of the passivation layer.

3. The light-emitting device as recited in claim 1, wherein the shielding layer and the first electrode are formed on the passivation layer simultaneously and the shielding layer is spaced from the first electrode are spaced in a distance.

4. The light-emitting device as recited in claim 1, wherein a pixel defined layer is formed on a part of the passivation layer as well as the first electrode and the shielding layer, with an opening placed thereon to expose a part or the whole of the upper surface of the first electrode.

5. The light-emitting device as recited in claim 4, wherein the organic light-emitting material layer of the organic illuminant and a second electrode are arranged in the opening.

6. The light-emitting device as recited in claim 4, wherein the oxide semiconductor layer is arranged on a part of the gate insulating layer as well as the source electrode and the drain electrode.

7. The light-emitting device as recited in claim 4, wherein the source electrode and the drain electrode are arranged on the oxide semiconductor layer.

8. The light-emitting device as recited in claim 2, wherein a pixel defined layer is formed on a part of the passivation layer as well as the first electrode and the shielding layer, with an opening placed thereon to expose a part or the whole of the upper surface of the first electrode.

9. The light-emitting device as recited in claim 3, wherein a pixel defined layer is formed on a part of the passivation layer as well as the first electrode and the shielding layer, with an opening placed thereon to expose a part or the whole of the upper surface of the first electrode.

10. A method for manufacturing a light-emitting device with an oxide thin film transistor, comprising steps of:
forming a substrate insulating layer on a substrate;
forming a gate electrode on the substrate insulating layer;
forming a gate insulating layer on the gate electrode and a part of the substrate insulating layer;
forming a source electrode and a drain electrode on the gate insulating layer, and then forming an oxide semiconductor layer on the gate insulating layer, wherein the oxide semiconductor layer comprises a source region and a drain region in contact with the source electrode and the drain electrode respectively and a channel region, so that the channel region is located between the source electrode and the drain electrode to form a conductive channel therebetween;
forming a passivation layer on a part of the gate insulating layer, the source electrode, the drain electrode, and the oxide semiconductor layer;
forming, on the passivation layer, a first electrode of an organic illuminant, a part of which penetrates through the passivation layer to contact with the source electrode or the drain electrode; and
forming a shielding layer to cover the whole oxide semiconductor layer at the time of forming the first electrode.

11. The method as recited claim 10, wherein the first electrode is extended along the upper surface of the passivation layer to form the shielding layer.

12. The method as recited claim 10, wherein the first electrode is spaced from the shielding layer in a certain distance.

13. The method as recited in claim 10, wherein a pixel defined layer is formed on a part of the passivation layer as well as the first electrode and the shielding layer, with an opening formed thereon to expose a part or the whole of upper surface of the first electrode.

14. The method as recited in claim 11, wherein a pixel defined layer is formed on a part of the passivation layer as well as the first electrode and the shielding layer, with an opening formed thereon to expose a part or the whole of upper surface of the first electrode.

15. The method as recited in claim 12, wherein a pixel defined layer is formed on a part of the passivation layer as well as the first electrode and the shielding layer, with an opening being formed thereon to expose a part or the whole of upper surface of the first electrode.

16. A method for manufacturing a light-emitting device with an oxide thin film transistor, comprising steps of:
forming a substrate insulating layer on a substrate;
forming a gate electrode on the substrate insulating layer;
forming a gate insulating layer on the gate electrode and a part of the substrate insulating layer;
forming, on the gate insulating layer, an oxide semiconductor layer comprising a source region, a drain region, and a channel region;
then, forming, on the gate insulating layer, a source electrode and a drain electrode being in contact with the source region and the drain region respectively;
forming a passivation layer on a part of the gate insulating layer, the source electrode, the drain electrode, and the oxide semiconductor layer;
forming, on the passivation layer, a first electrode of an organic illuminant, a part of which penetrates through the passivation layer to contact with the source electrode or the drain electrode; and
forming a shielding layer to cover the whole oxide semiconductor layer at the time of forming the first electrode.

17. The method as recited in claim 16, wherein the first electrode is extended along the upper surface of the passivation layer to form the shielding layer.

18. The method as recited in claim 16, wherein the first electrode is spaced from the shielding layer in a certain distance.

19. The method as recited in claim 16, wherein a pixel defined layer is formed on a part of the passivation layer as well as the first electrode and the shielding layer, with an opening formed thereon to expose a part or the whole of the upper surface of the first electrode.

20. The method as recited in claim 17, wherein a pixel defined layer is formed on a part of the passivation layer as well as the first electrode and the shielding layer, with an opening being formed thereon to expose a part or the whole of the upper surface of the first electrode.
